(19) United States
(12) Patent Application Publication
(10) Pub. No.: US 2025/0174293 A1
(43) Pub. Date: May 29, 2025

(54) CLOCK CONVERSION DEVICE, TEST SYSTEM INCLUDING THEREOF AND METHOD OF OPERATING THE TEST SYSTEM

(71) Applicant: Samsung Electronics Co., Ltd., Suwon-si (KR)

(72) Inventors: Jinuk Kim, Suwon-si (KR); Sunggu Lee, Suwon-si (KR)

(21) Appl. No.: 18/898,855

(22) Filed: Sep. 27, 2024

(30) Foreign Application Priority Data
Nov. 23, 2023 (KR) 10-2023-0164852

(51) Int. Cl. G11C 29/12; G01R 31/317; G06F 1/08; H03L 7/08

(52) U.S. Cl. CPC G11C 29/12015; G01R 31/31727; G06F 1/08; G11C 29/12005; H03L 7/08

(57) ABSTRACT

A clock conversion device includes a first clock generator configured to receive a clock signal from a test device and generate a first clock signal with a fixed multiplied frequency, a second clock generator separated from the first clock generator and configured to receive a clock signal from the test device and generate a second clock signal with a varying multiplied frequency, and a clock conversion circuit configured to receive the second clock signal, generate a third clock signal by changing a frequency of the second clock signal, and provide the third clock signal to a device under test (DUT) that is a test target.

### CROSS-REFERENCE TO RELATED APPLICATION(S)

This application is based on and claims priority under 35 U.S.C. § 119 to Korean Patent Application No. 10-2023-0164852, filed on Nov. 23, 2023, in the Korean Intellectual Property Office, the disclosure of which is incorporated by reference herein in its entirety.

### BACKGROUND

The inventive concept relates to a clock conversion device, and more particularly, to a clock conversion device capable of providing a device under test (DUT) with various types of clock signals, a test system including the clock conversion device, and a method of operating the test system.

A memory device may receive commands, addresses, and data from an external device. During mass production of memory devices, the memory devices may be tested as devices under test (DUTs), and as their speed may increase and various tests related to the memory devices may be conducted, a variety of clock signals may be required during test processes.

However, existing test systems for testing memory devices may operate at a speed lower than the operation speed of the memory devices, leading to a limitation in providing diverse clock signals to support different tests carried out for the memory devices.

### SUMMARY

The inventive concept provides a clock conversion device capable of supporting various tests for a memory device operating at high speed, a test system including the clock conversion device, and a method of operating the test system.

According to an aspect of the inventive concept, there is provided a clock conversion device includes a first clock generator configured to receive a clock signal from an external test device and generate a first clock signal with a fixed multiplied frequency, a second clock generator separated from the first clock generator and configured to receive a clock signal from the external test device and generate a second clock signal with a varying multiplied frequency, and a clock conversion circuit configured to receive the second clock signal from the second clock generator, generate a third clock signal by converting characteristics of the second clock signal, and provide the third clock signal to a device under test (DUT) that is a test target.

According to another aspect of the inventive concept, there is provided a test system including a plurality of sockets on which a plurality of DUTs are mounted, and a clock conversion device configured to generate an output clock signal provided to the plurality of DUTs. The clock conversion device includes a first clock generator configured to receive a clock signal from the outside and generate a first clock signal with a fixed multiplied frequency, a second clock generator separated from the first clock generator and configured to receive a clock signal from the outside and generate a second clock signal with a varying multiplied frequency, and a clock conversion circuit configured to receive the second clock signal and generate a third clock signal by changing a frequency of the second clock signal. The output clock signal is the same as the third clock signal.

According to another aspect of the inventive concept, there is provided a method of operating a test system including a clock conversion device configured to provide an output clock signal to a DUT, the method including generating, by the clock conversion device, a first clock signal with a fixed multiplied frequency, generating, by the clock conversion device, a second clock signal with a varying multiplied frequency, generating, by the clock conversion device, a third clock signal by changing a frequency of the second clock signal, and performing a test operation by providing the third clock signal to the DUT as the output clock signal.

### BRIEF DESCRIPTION OF THE DRAWINGS

Embodiments will be more clearly understood from the following detailed description taken in conjunction with the accompanying drawings in which:

FIG. 1 is a block diagram of a test system according to an embodiment;

FIGS. 2 and 3 are schematic block diagrams of a test system according to example embodiments;

FIG. 4 is a schematic block diagram of a test system according to an embodiment;

FIG. 5 is a flowchart of a method of operating a test system, according to an embodiment;

FIG. 6 is a flowchart of a method of operating a test system, according to an embodiment;

FIG. 7 is a timing diagram of signals of a test system according to an embodiment;

FIGS. 8 and 9 are a block diagram and a structure diagram, respectively, of an example in which clock conversion chips are arranged to correspond to multiple DUTs, according to example embodiments; and

FIG. 10 is a block diagram of an example in which a test device communicates with a memory device as a DUT, according to an embodiment.

### DETAILED DESCRIPTION OF THE EMBODIMENTS

Hereinafter, example embodiments are described in detail with reference to the attached drawings.

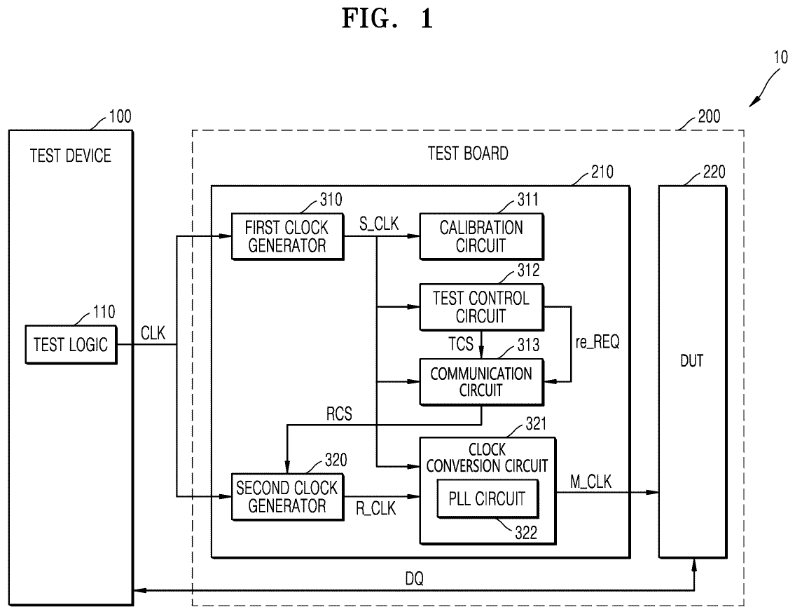

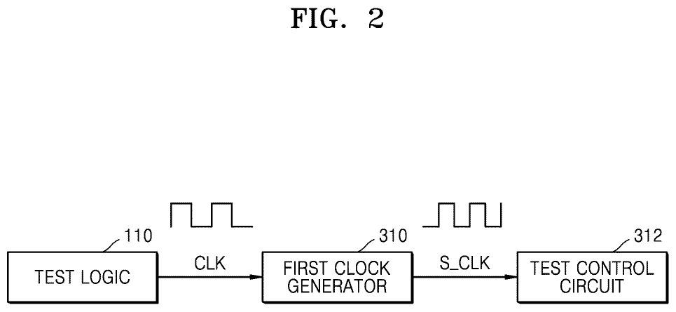

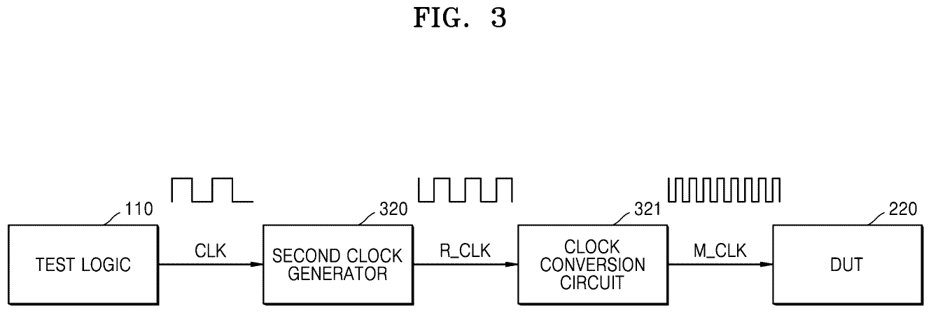

FIG. 1 is a block diagram of a test system 10 according to an embodiment. FIGS. 2 and 3 are schematic block diagrams of a test system according to example embodiments.

Referring to FIG. 1, the test system 10 for testing various types of semiconductor devices, such as memory devices, may include a test device 100 and a test board 200 on which one or more devices under test (DUTs) 220 are mounted, wherein tests are to be conducted on the DUTs 220. In addition, with regard to a test operation, various components may be included in the test board 200, and for example, the test board 200 may include a plurality of sockets (not shown) on which DUTs are mounted, and the above DUTs 220 may be mounted on the sockets. For convenience of explanation, FIG. 1 shows one DUT, but multiple sockets may be included in the test board 200, and multiple DUTs are mounted on the sockets; thus, the DUTs and the sockets may be tested together or simultaneously. In addition, as the test board 200 includes multiple sockets, the test board 200 may be referred to as a socket board.

According to various embodiments, the test device 100 may be arranged outside the test board 200 and communicate with the DUT 220 through the test board 200. In an embodiment, it may be described that the test device 100 and the test board 200 form the test system 10 and the DUT 220 communicates with the test device 100 through the test board 200 as the DUT 220 is arranged outside the test board 200.

The test device 100 may include a test logic 110 for controlling general test operations for the DUT 220. Although not shown in FIG. 1, the test device 100 may further include other components, for example, a communication device for communicating with an external host requesting tests, a memory temporarily storing different information associated with diverse tests, an interface circuit for communicating with the DUT 220, a power supply circuit (all of which are not shown) supplying power to the DUT 220, and the like. According to an embodiment, the test device 100 may include a semiconductor chip, such as a field programmable gate array (FPGA), an application specific integrated circuit (ASIC), or an application processor (AP), and such a semiconductor chip may perform a function of the test logic 110.

A test process for determining whether a semiconductor device has defects may be performed at various stages of the semiconductor process. For example, the test procedure according to an embodiment may include testing a semiconductor package in which one semiconductor die (or a semiconductor chip) is packaged. Alternatively, the test procedure may include testing a semiconductor package including multiple semiconductor chips. Furthermore, the test procedure may include testing a semiconductor wafer including multiple semiconductor dies.

The DUT 220 may be a semiconductor device of various types and be, for example, a memory device including a memory cell array. For example, the memory device may be dynamic random access memory (DRAM), such as double data rate synchronous dynamic random access memory (DDR SDRAM), low power double data rate (LPDDR) SDRAM, graphics double data rate (GDDR) SDRAM, or Rambus dynamic random access memory (RDRAM). Alternatively, the memory device may be non-volatile memory, such as flash memory, magnetic RAM (MRAM), ferroelectric RAM (FeRAM), phase change RAM (PRAM), or resistive RAM (ReRAM).

According to embodiments, the test board 200 may include a clock conversion device 210, and for example, the clock conversion device 210 may be realized as a semiconductor chip and mounted on the test board 200. For example, the test board 200 may include a printed circuit board (PCB) that transmits, to the DUT 220, various signals from the test device 100, and the clock conversion device 210 mounted on the PCB may receive a clock signal from the test device 100 and may provide the DUT 220 with an output clock signal generated through a signal conversion process.

The clock conversion device 210 may provide the DUT 220 with a clock signal with various clock characteristics (or frequency), based on a clock generation operation and/or a clock conversion operation. Through a conversion process on a clock signal CLK provided from the outside (e.g., the test device 100), the clock conversion device 210 may provide the DUT 220 with one or more clock signals (hereinafter, referred to as output clock signals) with clock characteristics that are different from that of the clock signal CLK. In embodiments below, the term “clock characteristics” may include various features related to waveforms of signals, wherein examples of the features include the frequency of a clock signal, a duty ratio (or a duty cycle), a clock activation state, and the like.

The clock conversion device 210 may include a first clock generator 310, a second clock generator 320, a calibration circuit 311, a test control circuit 312, a communication circuit 313, and a clock conversion circuit 321.

The first clock generator 310 may generate a first clock signal S_CLK obtained by increasing the frequency of the input clock signal CLK by a fixed multiplying factor. For example, a frequency of the first clock signal S_CLK may be fixed to one of various frequencies during the test on DUT 220. The first clock signal S_CLK may be a system clock signal. The second clock generator 320 may generate a second clock signal R_CLK that is obtained by increasing the frequency of the input clock signal CLK by a varying multiplying factor. For example, the clock conversion device 210 may change a frequency of the second clock signal R_CLK when a clock signal provided to the DUT 220 needs to be changed. The second clock signal R_CLK may be a reference clock signal.

For example, referring to FIGS. 1 to 3, the first clock generator 310 may generate the first clock signal S_CLK with a frequency that is five times the frequency of the clock signal CLK, and the second clock generator 320 may generate the second clock signal R_CLK with a frequency that is 3.3 times the frequency of the clock signal CLK. For example, when a frequency of the clock signal CLK is 10 MHz, the frequency of the first clock signal S_CLK may be about 50 MHz, and the frequency of the second clock signal R_CLK may be about 33 MHz. In an embodiment, the test device 100 may provide a first clock input signal CLK1 to the first clock generator 310 and provide a second clock input signal CLK2 to the second clock generator 320.

The clock conversion circuit 321 may include a phase-locked loop (PLL) circuit 322, and the PLL circuit 322 may include one or more voltage controlled oscillators (not shown). For example, when the PLL circuit 322 includes a plurality of voltage controlled oscillators, the clock conversion circuit 321 may generate clock signals (e.g., third clock signals) with frequencies increased by various multiples.

For example, the clock conversion circuit 321 may receive the second clock signal R_CLK and generate a third clock signal M_CLK having a frequency that is increased compared to that of the second clock signal R_CLK. In an embodiment, the clock conversion circuit 321 may receive the second clock signal R_CLK from the second clock generator 320 and generate the third clock signal M_CLK by variously adjusting clock characteristics including the frequency, the duty, and the like of the second clock signal R_CLK.

For example, referring to FIGS. 1 to 3, the clock conversion circuit 321 may generate the third clock signal M_CLK with frequencies that are variously increased, for example, 2, 4, 8, 24, and 48 times, compared to the frequency of the second clock signal R_CLK. The clock conversion circuit 321 may generate the third clock signal M_CLK having an increased frequency that is 24 times the frequency of the second clock signal R_CLK. For example, when the frequency of the second clock signal R_CLK is 33 MHz, the frequency of the third clock signal M_CLK may be about 800 MHz.

Referring back to FIG. 1, the calibration circuit 311 may receive the first clock signal S_CLK. The calibration circuit 311 may perform a calibration operation on the first clock signal S_CLK in response to a calibration request signal and complete the calibration operation on the first clock signal S_CLK in response to a calibration completion signal. In addition, the calibration circuit 311 may perform the calibration operation again on the first clock signal S_CLK in response to a re-calibration request signal. The calibration circuit 311 may adjust the duty of the first clock signal S_CLK.

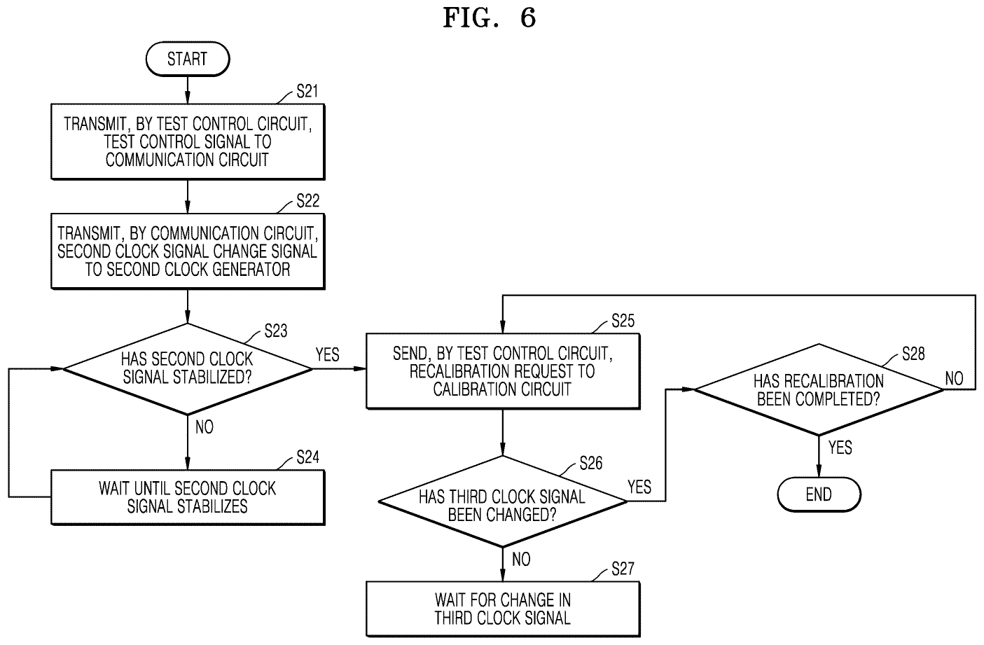

The test control circuit 312 may control a test sequence of the test board 200. The test control circuit 312 may provide a re-calibration request signal re_REQ to the communication circuit 313. The test control circuit 312 may receive the first clock signal S_CLK, and when a test sequence needs to be controlled, the test control circuit 312 may generate a test sequence control signal TCS and provide the same to the communication circuit 313. A method of controlling a test sequence is described below with reference to FIG. 6.

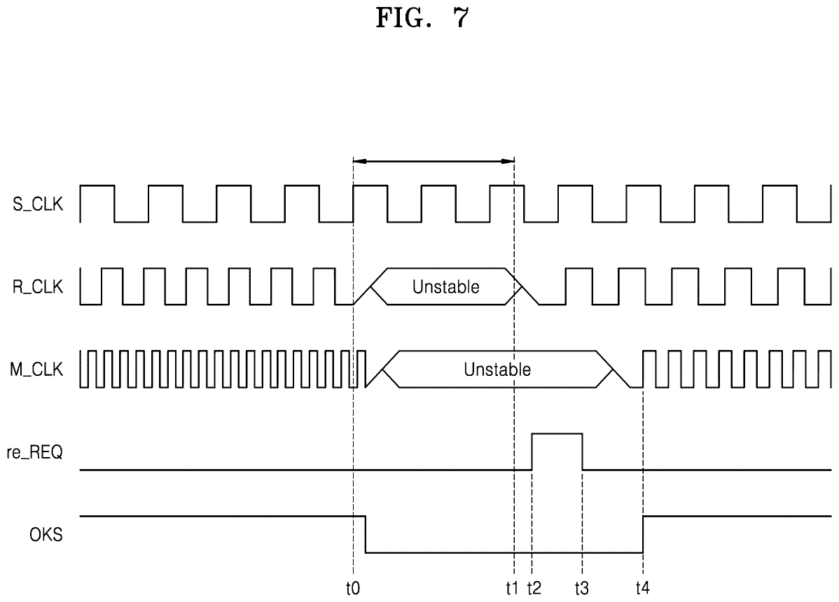

The communication circuit 313 may receive the first clock signal S_CLK. In response to the test sequence control signal TCS, the communication circuit 313 may generate a rate change signal RCS when a change in the frequency of the third clock signal M_CLK is needed. The generated rate change signal RCS may be provided to the second clock generator 320 and thus allow the frequency or rate of the second clock signal R_CLK to be changed. In an embodiment, the communication circuit 313 may use communication protocols, such as Inter-Integrated Circuit (I2C), Serial Peripheral Interface (SPI), Universal Asynchronous Receiver-Transmitter (UART), and Peripheral Component Interconnect Express (PCIe). A method of changing the frequency of the second clock signal R_CLK is described below with reference to FIGS. 6 and 7.

When the frequency of the clock signal provided to the DUT 220 is changed, an operation of the conversion device 210 may become unstable. However, the conversion device 210 may operate in a stable state by providing the first clock signal S_CLK with a fixed frequency to the calibration circuit 311, the test control circuit 312, and the communication circuit 313 of the conversion device 210.

The third clock signal M_CLK generated from the clock conversion circuit 321 may be provided to the DUT 220. The DUT 220 may receive the third clock signal M_CLK and perform various operations based on the third clock signal M_CLK. The third clock signal M_CLK may be referred to as an output clock signal.

According to an embodiment, the DUT 220 may receive/transmit data corresponding to a test pattern from/to the test device 100 and may receive/transmit the data from/to the test device 100 in response to the third clock signal M_CLK. For example, when the DUT 220 includes GDDR-based DRAM, the DUT 220 may receive the third clock signal M_CLK as a record clock signal (a WCK signal according to Joint Electron Device Engineering Council (JEDEC) standards). Alternatively, when the DUT 220 includes DRAM based on LPDDR standards, the DUT 220 may receive the third clock signal M_CLK as a data strobe signal (a DQS signal according to JEDEC standards). For example, when the DUT 220 includes a memory device, the third clock signal M_CLK may be a memory clock signal. The third clock signal M_CLK may be provided to the DUT 220 as an output clock signal, and clock characteristics of the output clock signal provided to the DUT 220 may be variously adjusted.

According to an embodiment, when the memory device is tested as a DUT, it is necessary to conduct tests by changing the duty of the clock signal to perform various tests, such as effective window margins of data, during data writing and reading processes. According to embodiments, as third clock signals M_CLK having different duty ratios are provided to a DUT, a variety of tests may be conducted.

Also, according to an embodiment, the DUT 220 receives the third clock signal M_CLK through the clock conversion device 210, while the data DQ may be directly received by the test device 100 through lines and sockets arranged in the test board 200.

According to an embodiment, even though the bandwidth of the clock signal CLK that may be provided by the test logic 110 is limited to x Gbps (for example, x is an integer), output clock signals in broadband (e.g., from about 0 Gbps to about 32 Gbps) may be provided to the DUT 220 as various clock generators and clock conversion circuits are integrated on the test board 200.

According to a Comparative Example, the clock conversion device 210 receives a clock signal CLK and simultaneously generates a first clock signal S_CLK, which is a system clock signal, and a second clock signal R_CLK, which is a reference clock signal from one clock generator. In this case, an issue may arise where the characteristic or the frequency of the first clock signal S_CLK generated by the clock generator may not be changed once the frequency of the first clock signal S_CLK is fixed. According to the Comparative Example, the change in the frequency of the second clock signal R_CLK, which is the basis of the third clock signal M_CLK provided to the DUT 220, requires the change in the clock signal CLK, which in turn leads to the adjustment in the frequency of the first clock signal S_CLK. In this case, the initialization process needs to be performed again due to the abnormal operation of the test control circuit 312, which operates by receiving the first clock signal S_CLK, and thus, the setup time required for testing a DUT increases according to the frequency changes.

However, according to an embodiment, the clock conversion device 210 may separately include the first clock generator 310, which generates the first clock signal S_CLK that is the system clock signal, and the second clock generator 320, which generates the second clock signal R_CLK that is the reference clock signal. Through independent generation of the first clock signal S_CLK and the second clock signal R_CLK, it is possible to stably maintain the frequency of the first clock signal S_CLK even when the frequency of the second clock signal R_CLK, which is the basis of the third clock signal M_CLK provided to the DUT 220, is changed, thereby stably executing a calibration operation and the like.

Also, as the first clock generator 310 is separate from the second clock generator 320, it may be possible to provide the DUT 220 with the third clock signal M_CLK having different clock characteristics by adjusting various clock characteristics of the second clock signal R_CLK and changing the duty or frequency of the second clock signal R_CLK, and thus a variety of tests may be conducted on the DUT 220.

An operation of generating various clock signals of the clock conversion device 210 and an operation of controlling the generation of the clock signals may be performed by a hardware circuit, a software component, or a combination thereof.

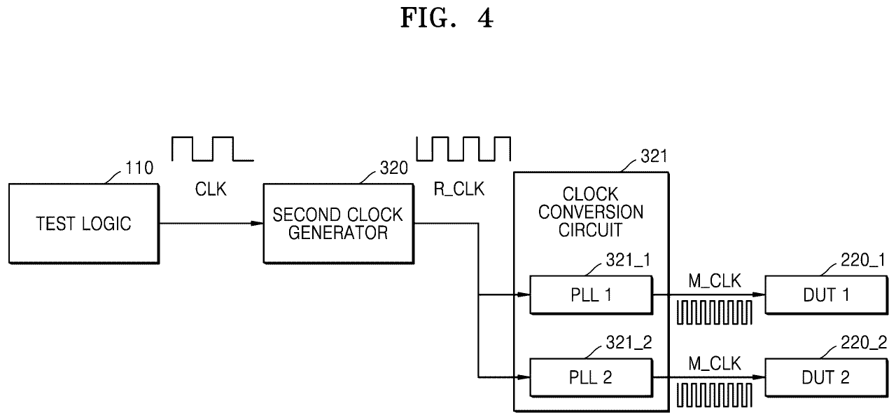

FIG. 4 is a schematic block diagram of a test system according to an embodiment.

Referring to FIG. 4, the clock conversion circuit 321 may include a first PLL circuit 321_1 and a second PLL circuit 321_2, and the test system 10 may include a first DUT 220_1 and a second DUT 220_2.

Each of the PLL circuits 321_1 and 321_2 may include a fan-out buffer (FOB) and an output driver circuit along with various clock generators and the clock conversion circuits according to the example embodiments described above. The FOB may include a circuit that expands one output clock signal into multiple signals, and for example, the output clock signal is expanded into the third clock signal M_CLK. In an embodiment, the PLL circuit 321_1 may generate N third clock signals M_CLK having the same frequency as each other, N is an integer of at least 2. In this case, the PLL circuit 321_1 may include a FOB expanding the third clock signal to N third clock signals and an output driver circuit including N output drivers outputting the N third clock signals M_CLK. In an embodiment, the PLL circuit 321_2 may generate P third clock signals M_CLK having the same frequency as each other, P is an integer of at least 2. In this case, the PLL circuit 321_2 may include a FOB expanding the third clock signal to P third clock signals and an output driver circuit including P output drivers outputting the P third clock signals M_CLK.

The output driver circuit may include one or more output drivers, and each output driver may receive the third clock signal M_CLK from the FOB and amplify the same to thus provide the third clock signal M_CLK to the DUTs 220_1 and 220_2. FIG. 4 shows that as the FOB generates two third clock signals (e.g., output clock signals), the output driver circuit includes two output drivers. Also, the output drivers that are enabled for operation in the output driver circuit may be selected based on a selection signal from the test logic 110.

The PLL circuit 322 in FIG. 1 may change a frequency band of an input clock and generate the third clock signal M_CLK with a changed frequency. For example, the PLL circuit 322 may include a plurality of voltage controlled oscillators for variously changing the frequency band of the input clock and thus generate the third clock signals M_CLK having various frequency bands that are, for example, 2 times, 4 times, 8 times, etc., the frequency of the input clock. For example, the PLL circuit 322 may receive the second clock signal R_CLK and generate the third clock signal M_CLK having a multiplied frequency.

However, the example embodiments are not limited thereto. The frequency band may be adjusted at various ratios, and the number of clocks in other frequency bands may also be variously adjusted.

According to the embodiments described above, a plurality of sockets used to mount the DUTs on the test board may be included, and each of the DUTs 220_1 and 220_2 may receive an output clock signal from the clock conversion device. According to embodiments, the clock conversion device may be arranged to correspond to one or more sockets (or one or more DUTs), and a plurality of third clock signals M_CLK may be provided to two different DUTs 220_1 and 220_2. The number of PLL circuits and the number of DUTs of FIG. 4 are not limited thereto and may be variously modified.

Also, in an embodiment, some output drivers in the output driver circuit may be disabled, and a determination regarding whether such output drivers are used may be made based on applications of the test device, the amount of power consumption supported by the test device, and the like.

According to embodiments, as the clock conversion device of the inventive concept is provided to an existing test system to test DRAM, such as GDDR or LPDDR, which operates in a high-frequency band, a test device capable of generating clock signals in a relatively low-frequency band may be utilized to test the DRAM operating at high speed. For example, even if the test device provides a clock signal in a low-frequency band, clock signals in a high-frequency band may be generated by the clock conversion device, and thus, the DRAM operating in the high-frequency band may be tested using the existing test device.

In addition, because output clock signals featuring different clock characteristics may be provided to the DUT according to the clock conversion operation according to example embodiments, it may be possible to conduct diverse tests on the DUT. As another example, when the DUT is tested by using a semiconductor chip such as an FPGA, clock signals with various characteristics and frequencies may be provided to the DUT without a change in FPGA configurations (or images), enabling the performance of a wide range of tests. For example, the clock conversion circuit 321 may include a FPGA.

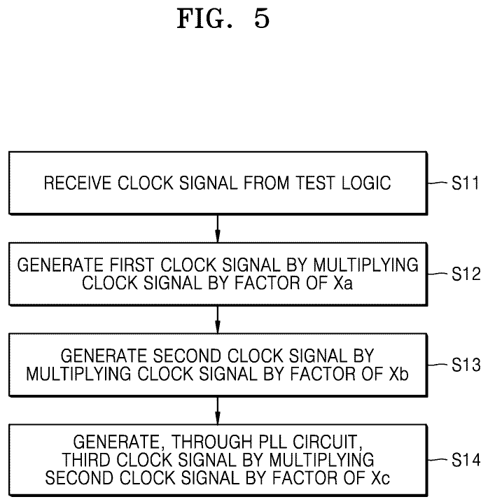

FIG. 5 is a flowchart of a method of operating a test system, according to an embodiment. Operations in the embodiment of FIG. 5 may correspond to operations of a test board or a clock conversion device mounted on the test board.

Referring to FIG. 5, DUTs may be mounted on a plurality of sockets arranged in the test board, and in operation S11, the clock conversion device according to an embodiment may receive a clock signal from a test logic of a test device.

In operation S12, the clock conversion device may generate a first clock signal S_CLK with a frequency multiplied by a factor of Xa (where a is an integer) with respect to the clock signal CLK received from the test device. In operation S13, the clock conversion device 210 may generate a second clock signal R_CLK with a frequency multiplied by a factor of Xb (where b is an integer) with respect to the clock signal CLK received from the test device.

For example, referring to FIGS. 1 to 4, the first clock generator 310 may receive the clock signal CLK and may generate the first clock signal S_CLK (e.g., a system clock) by increasing the frequency of the clock signal CLK by a multiplication factor (a times, where a is an integer). The second clock generator 320 may receive the clock signal CLK and generate the second clock signal R_CLK (for example, a reference clock) by increasing the frequency of the clock signal CLK by a multiplication factor (b times, where b is an integer).

Referring back to FIG. 5, in operation S14, the clock conversion device may use the clock conversion circuit 321, which receives the second clock signal R_CLK, to generate the third clock signal M_CLK with a frequency multiplied by a factor of Xc (where c is an integer) with respect to the second clock signal R_CLK. The third clock signal M_CLK may be a clock signal used to test the DUTs.

For example, referring to FIG. 1, the clock conversion circuit 321 may include the PLL circuit 322 and use the PLL circuit 322 to generate the third clock signal M_CLK with a frequency that is variously increased compared to the frequency of the second clock signal R_CLK.

Accordingly, the test system may provide the DUT with a third clock signal (e.g., an output clock signal) with a multiplied frequency and may conduct a test on the DUT operating at high speed. Also, the clock conversion device may include a clock conversion circuit that changes output clock frequency from the PLL circuit according to the embodiments above and output, to the DUT, the third clock signal M_CLK generated by changing the output clock frequency from the PLL circuit. Accordingly, the test system may vary the clock frequency of the output clock signal and provide the same to the DUT to conduct a variety of tests during the test process for the DUT.

According to an embodiment, the test system may separately generate the first clock signal S_CLK and the second clock signal R_CLK. As the test system generates the first clock signal S_CLK and the second clock signal R_CLK separately, the frequency of the first clock signal S_CLK may remain stable even if the frequency of the second clock signal R_CLK, the basis of the third clock signal M_CLK provided to the DUT, is changed, and thus, the test system may stably perform a calibration operation.

Also, by adjusting various clock characteristics of the second clock signal R_CLK and changing the duty or frequency of the second clock signal R_CLK, the third clock signal M_CLK with different clock characteristics may be provided to the DUT 220, and thus, a wide range of tests may be performed on the DUT 220.

FIG. 6 is a flowchart of a method of operating a test system, according to an embodiment. In FIG. 6, it is assumed that the DUT includes a memory device. Also, methods of operating a test system of FIG. 6 are described under the assumption that the frequency of the third clock signal M_CLK provided to the DUT is to be changed.

Referring to FIGS. 1 and 6 together, in operation S21, the test control circuit 312 may transmit a test sequence control signal TCS to the communication circuit 313. For example, when the frequency of the second clock signal R_CLK, the basis of the third clock signal M_CLK, is changed to change the frequency of the third clock signal M_CLK provided to the DUT, test sequence control may be required. In this case, the test control circuit 312 may generate the test sequence control signal TCS and provide the same to the communication circuit 313.

In operation S22, the communication circuit 313 may transmit a rate change signal RCS to the second clock generator 320. For example, the communication circuit 313 may generate the rate change signal RCS in response to the test sequence control signal TCS. The generated rate change signal RCS may be provided to the second clock generator 320. The second clock generator 320 may receive the rate change signal RCS and change the frequency or the rate of the second clock signal R_CLK.

In operation S23, the second clock generator 320 may check whether the second clock signal R_CLK has stabilized. When the second clock signal R_CLK has not stabilized (NO in operation S23), the second clock generator 320 may wait until the second clock signal R_CLK stabilizes in operation S24.

On the contrary, when the second clock signal R_CLK has stabilized (YES in operation S23), the test control circuit 312 may transmit a re-calibration request signal re_REQ to the calibration circuit 311 in operation S25. Alternatively, in another embodiment, it may also be possible to transmit a signal similar to the re-calibration request signal re_REQ to another circuit that may perform a similar function to that of the calibration circuit 311.

In operation S26, the clock conversion device 210 may change and output the third clock signal M_CLK. In operation S27, when the third clock signal M_CLK has not been changed (NO in operation S26), the clock conversion device 210 may wait until the third clock signal M_CLK undergoes a change. On the contrary, when the third clock signal M_CLK is changed (YES in operation S26), the clock conversion device 210 may check whether recalibration has been completed in operation S28. When the calibration circuit 311 has not completed the recalibration (NO in operation S28), the clock conversion device 210 may return to operation S25 and transmit the re-calibration request signal re_REQ to the calibration circuit 311. On the contrary, when recalibration has been completed (YES in operation S28), the calibration circuit 313 may complete the calibration operation in response to a calibration completion signal.

FIG. 7 is a timing diagram of signals of a test system according to an embodiment. It is assumed in FIG. 7 that the frequency of the third clock signal M_CLK provided to the DUT needs to be changed.

Referring to FIG. 7, in a first period from t0 to t1, the second clock signal R_CLK and the third clock signal M_CLK may be unstable. Because it is required to change the frequency of the third clock signal M_CLK provided to the DUT in the first period from t0 to t1, the second clock signal R_CLK, which is the basis of the third clock signal M_CLK, may be changed and thus remain unstable.

In a second period from t1 to t2, when the second clock signal R_CLK is stable, the re-calibration request signal re_REQ may transition from a first level (e.g., a logic low level) to a second level (e.g., a logic high level). Referring to FIGS. 1 and 6, for example, the calibration circuit 311 may perform the calibration operation again in response to the re-calibration request signal re_REQ. In the second period from t1 to t2, the second clock signal R_CLK and the third clock signal M_CLK may remain unstable.

In a third period from t2 to t3, when the second clock signal R_CLK keeps being in the stable state, the re-calibration request signal re_REQ may transition from the second level to the first level. For example, referring to FIGS. 1 and 6, the second clock generator 320 checks whether the second clock signal R_CLK has stabilized, and when the second clock signal R_CLK is stabilized, the calibration circuit 311 may turn off the re-calibration request signal re_REQ. For example, in the third period from t2 to t3, the second clock signal R_CLK may stabilize, but the third clock signal M_CLK may remain unstable. Here, the description that the state of the second clock signal R_CLK is maintained in a stable state may imply that the frequency of the second clock signal R_CLK is changed and the second clock generator 320 generates the changed frequency of the second clock signal R_CLK (e.g., a Lock state).

In a fourth period from t3 to t4, the level of a calibration completion signal OKS may transition from a second level to a first level. Because the second clock signal R_CLK continues to stabilize and the operation of the calibration circuit 311 is completed, the calibration completion signal OKS may be turned off. Thus, after the fourth period from t3 to t4, the state of the third clock signal M_CLK may also be maintained in a stable state. Here, the description that the state of the third clock signal M_CLK is maintained in the stable state may imply that the frequency of the third clock signal M_CLK is changed and the clock conversion circuit 321 generates the changed frequency of the third clock signal M_CLK.

The test system according to an embodiment may generate the first clock signal S_CLK and the second clock signal R_CLK separately, and even when the frequency of the second clock signal R_CLK functioning as the basis of the third clock signal M_CLK provided to the DUT 220 is changed, the frequency of the first clock signal S_CLK remains unchanged and stable, and thus, the test system may stably perform the calibration operation and the like.

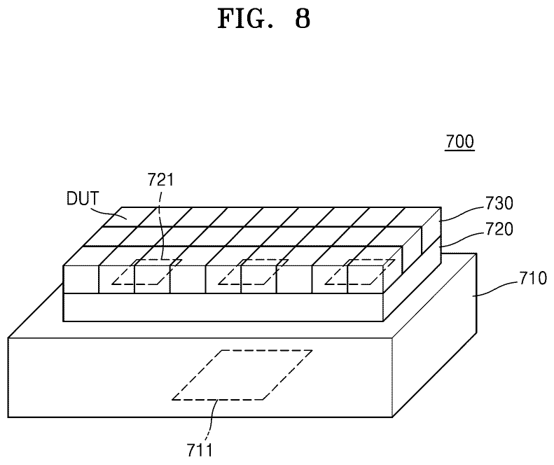

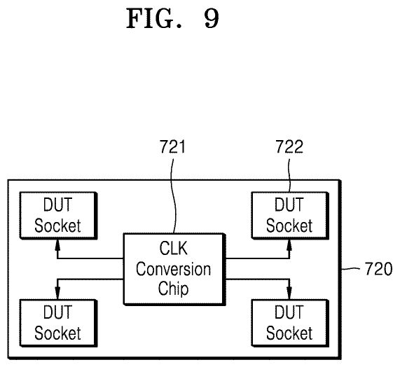

FIGS. 8 and 9 are a block diagram and a structure diagram, respectively, of an example in which clock conversion chips are arranged to correspond to multiple DUTs, according to example embodiments.

Referring to FIG. 8, a test system 700 may include a test device 710 and a test board 720, and the test device 710 may include a test logic 711. Also, the test board 720 may include one or more clock conversion chips 721, and the clock conversion chips 721 may correspond to the clock conversion device 210 according to example embodiments described above. In addition, the test board 720 may include a plurality of sockets, and the DUTs 730 may be mounted on the sockets.

The test system 700 may be a device referred to as automatic test equipment (ATE) or a test device based on FPGA or ASIC.

FIG. 9 shows an example in which the test board 720 includes the clock conversion chip 721 and the sockets 722, and for example, the clock conversion chip 721 is arranged to correspond to four sockets 722. According to example embodiments, the clock conversion chip 721 may generate a plurality of output clock signals, and the plurality of output clock signals may be provided to one or more DUTs. FIG. 9 shows an example in which the clock conversion chip 721 provides the output clock signals to the DUTs mounted on four sockets 722, and the arrangements of the clock conversion chip 721 and the sockets 722 on the test board 720 may be variously modified.

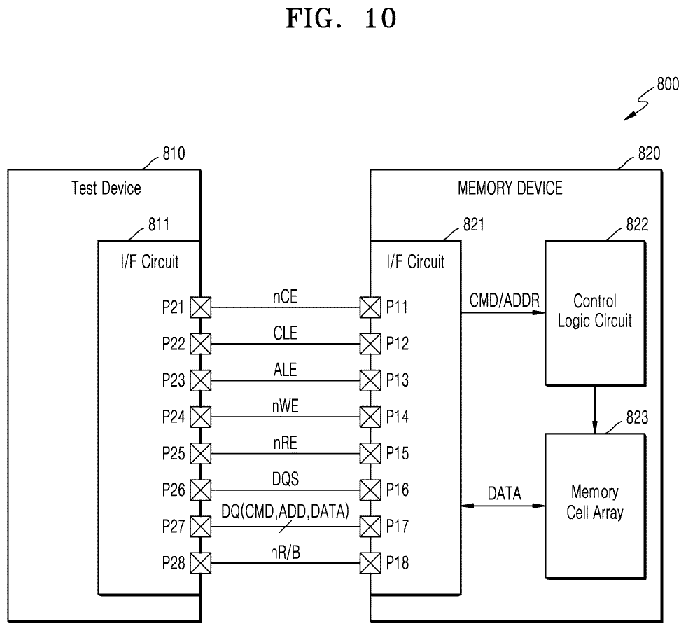

FIG. 10 is a block diagram of an example in which a test device 810 communicates with a memory device 820 as a DUT, according to an embodiment.

As shown in FIG. 10, a test system 800 may include the test device 810, and the memory device 820 may be mounted on the test board as the DUT. According to example embodiments, the test system 800 may further include the test board including one or more overlapping lines, and FIG. 10 does not specifically illustrate the lines.

The memory device 820 may include an interface circuit 821, a control logic circuit 822, and a memory cell array 823. The interface circuit 821 may communicate with the test device 810 through a first pin P11 to an eighth pin P18. For example, the memory device 820 may receive a chip enable signal nCE through the first pin P11, and when the chip enable signal nCE is in an enabled state, the memory device 820 may receive/transmit various signals through the second pin P12 to the eighth pin P18.

Also, the memory device 820 may receive a command latch enable signal CLE, an address latch enable signal ALE, and a write enable signal nWE through the second pin P12 to the fourth pin P14. Moreover, the memory device 820 may receive/transmit an input/output signal DQ through the seventh pin P17, and for example, the memory device 820 may receive a command/address/data or transmit data to the test device 810 through the seventh pin P17. For example, the seventh pin P17 may include a plurality of pins, and the input/output signal DQ may be transmitted through a plurality of signal lines.

For example, the memory device 820 may obtain a command CMD in an enable period of the command latch enable signal CLE, based on toggle timings of the write enable signal nWE. Also, the memory device 820 may obtain an address ADDR in an enable period of the address latch enable signal ALE, based on the toggle timings of the write enable signal nWE.

The memory device 820 may receive a read enable signal nRE through the fifth pin P15, receive the data strobe signal DQS through the sixth pin P16, or transmit the data strobe signal DQS to the test device 810. In an operation in which the memory device 820 outputs data DATA, the data DATA may be transmitted to the test device 810 based on a toggle timing of the data strobe signal DQS. Also, in an operation in which the memory device 820 receives the data DATA, the data DATA may be obtained based on the toggle timing of the data strobe signal DQS from the test device 810. Also, the memory device 820 may transmit, to the test device 810, a ready/busy output signal nR/B through the eighth pin P18. For example, when the memory device 820 is in a busy state (that is, when internal operations of the memory device 820 are in progress), the memory device 820 may transmit, to the test device 810, the ready/busy output signal nR/B indicating the busy state.

The control logic circuit 822 may control various operations of the memory device 820 overall. The control logic circuit 822 may generate control signals for controlling other components of the memory device 820, according to the command CMD and/or the address ADDR obtained from the interface circuit 821. For example, the control logic circuit 822 may generate various control signals for storing the data DATA in the memory cell array 823 or reading the data DATA from the memory cell array 823. The memory cell array 823 may store the data DATA, which is obtained from the interface circuit 821, according to the control of the control logic circuit 822. The memory cell array 823 may output the stored data DATA to the interface circuit 821, according to the control of the control logic circuit 822.

The test device 810 may include the interface circuit 811 and communicate with the memory device 820 through a first pin P21 to an eighth pin P28. The first pin P21 to the eighth pin P28 of the test device 810 may correspond to the first pin P11 to the eighth pin P18 of the memory device 820, and detailed descriptions thereof are omitted because the communication operations using the above pins may be described by referring to the descriptions provided for the memory device 820.

According to an embodiment, when referring to the interface circuit 811, the pins to which the overlapping lines are applied may be applied to at least some of the first pin P21 to the eighth pin P28 of the test device 810.

The test device 810 according to an embodiment may separately generate a first clock signal, which is a system clock signal, and a second clock signal, which is a reference clock signal. Even when the frequency of the second clock signal that is the basis of the third clock signal provided to the memory device 820 is changed, the frequency of the first clock signal remains stable, ensuring the normal operation of the test control circuit and the stable execution of the calibration operation by the test device 810.

Also, it may be possible to provide the memory device 820 with the third clock signal having different clock characteristics by adjusting various clock characteristics of the second clock signal and changing the duty or frequency of the second clock signal, and thus a variety of tests may be conducted on the memory device 820.

While the inventive concept has been particularly shown and described with reference to embodiments thereof, it will be understood that various changes in form and details may be made therein without departing from the spirit and scope of the present invention as set forth in the following claims.

What is claimed is:

1. A clock conversion device comprising:
a first clock generator configured to receive a clock signal from an external test device and generate a first clock signal with a fixed multiplied frequency;
a second clock generator separated from the first clock generator and configured to receive a clock signal from the external test device and generate a second clock signal with a varying multiplied frequency; and
a clock conversion circuit configured to:
receive the second clock signal from the second clock generator,
generate a third clock signal by changing a frequency of the second clock signal, and
provide the third clock signal to a device under test (DUT) that is a test target.

2. The clock conversion device of claim 1, wherein the first clock signal is a system clock, and the second clock signal is a reference clock.

3. The clock conversion device of claim 1, wherein the DUT is a memory device, and
wherein the third clock signal is a memory clock obtained by multiplying a frequency of the second clock signal.

4. The clock conversion device of claim 1, wherein the clock conversion circuit includes:
a phase locked loop (PLL) circuit configured to receive the second clock signal and generate the third clock signal with a frequency multiplied with respect to the frequency of the second clock signal.

5. The clock conversion device of claim 4, wherein the PLL circuit includes:
a plurality of voltage controlled oscillators configured to multiply the frequency of the second clock signal by identical multiples.

6. The clock conversion device of claim 4, wherein the PLL circuit further comprises:
a fan-out buffer configured to expand the third clock signal to N third clock signals, wherein N is an integer of at least 2; and
an output driver circuit comprising N output drivers arranged to correspond to the N third clock signals and configured to output the N third clock signals to the DUT.

7. The clock conversion device of claim 1, further comprising:
a calibration circuit configured to receive the first clock signal and adjust a duty ratio of the first clock signal;
a test control circuit configured to receive the first clock signal and generate a test sequence control signal; and
a communication circuit configured to receive the first clock signal and generate a rate change signal in response to the test sequence control signal,
wherein, when the third clock signal is to be changed, the clock conversion device is configured such that communication circuit provides the rate change signal to the second clock generator.

8. The clock conversion device of claim 7, wherein, when the third clock signal provided to the DUT needs to be changed, the clock conversion device is configured such that the second clock generator changes the second clock signal in response to the rate change signal.

9. The clock conversion device of claim 8, wherein the second clock generator is configured to generate the changed second clock signal,
wherein the calibration circuit is configured to perform calibration on the first clock signal in response to a calibration request signal and finish performing the calibration on the first clock signal in response to a calibration completion signal, and
wherein the clock conversion circuit is configured to provide the changed third clock signal to the DUT.

10. A test system comprising:
a plurality of sockets on which a plurality of devices under test (DUTs) are mounted; and
a clock conversion device configured to generate an output clock signal provided to the plurality of DUTs,
wherein the clock conversion device comprises:
a first clock generator configured to receive a clock signal from the outside and generate a first clock signal with a fixed multiplied frequency;
a second clock generator separated from the first clock generator and configured to receive a clock signal from the outside and generate a second clock signal with a varying multiplied frequency; and
a clock conversion circuit configured to receive the second clock signal and generate a third clock signal by changing a frequency of the second clock signal,
wherein the output clock signal is the same as the third clock signal.

11. The test system of claim 10, further comprising:
a test device including a test logic configured to generate the clock signal and control a test operation performing on the plurality of DUTs.

12. The test system of claim 10, wherein the first clock signal is a system clock, and the second clock signal is a reference clock, and
wherein, when each of the plurality of DUTs is a memory device, the third clock signal is a memory clock obtained by multiplying a frequency of the second clock signal.

13. The test system of claim 10, wherein the clock conversion circuit comprises a phase locked loop (PLL) circuit configured to receive the second clock signal and generate the third clock signal with a frequency multiplied with respect to the frequency of the second clock signal.

14. The test system of claim 10, wherein the clock conversion device further comprises:
a calibration circuit configured to receive the first clock signal and adjust a duty ratio of the first clock signal;
a test control circuit configured to receive the first clock signal and generate a test sequence control signal; and
a communication circuit configured to receive the first clock signal and generate a rate change signal in response to the test sequence control signal,
wherein the test system is configured such that the communication circuit provides the rate change signal to the second clock generator when a frequency of the third clock signal is changed.

15. The test system of claim 14, wherein, when the third clock signal provided to the plurality of DUTs needs to be changed, the test system is configured such that the clock conversion circuit changes only the second clock signal in response to the rate change signal.

16. The test system of claim 15, wherein the second clock generator is configured to generate the changed second clock signal,
wherein the calibration circuit is configured to perform calibration in response to a calibration request signal and finish performing the calibration in response to a calibration completion signal, and
wherein the clock conversion circuit is configured to provide the changed third clock signal to the plurality of DUTs.

17. The test system of claim 10, wherein the PLL circuit further comprises:
a fan-out buffer configured to expand the third clock signal to N third clock signals wherein N is an integer of at least 2; and
an output driver circuit comprising N output drivers arranged to correspond to the N third clock signals and configured to output the N third clock signals to the plurality of DUTs.

18. A method of operating a test system including a clock conversion device configured to provide an output clock signal to a device under test (DUT), the method comprising:
generating, by the clock conversion device, a first clock signal with a fixed multiplied frequency;
generating, by the clock conversion device, a second clock signal with a varying multiplied frequency;
generating, by the clock conversion device, a third clock signal by changing a frequency of the second clock signal; and
performing a test operation by providing the third clock signal to the DUT as the output clock signal.

19. The method of claim 18, wherein the performing of the test operation comprises:
generating, in response to a rate change signal, the second clock signal with the changed frequency;
performing calibration operation in response to a calibration request signal;
finishing the calibration operation in response to a calibration completion signal; and
generating the third clock signal with a changed frequency and providing the DUT with a changed third clock signal as the output clock signal.

20. The method of claim 18, wherein the generating of the first clock signal includes generating the first clock signal by multiplying a clock signal received from a test device of the test system by a times, wherein a is an integer,
wherein the generating of the second clock signal includes generating the second clock signal by multiplying the clock signal by b times, wherein b is an integer different from a, and
wherein the generating of the third clock signal includes generating the third clock signal by multiplying the second clock signal by c times, wherein c is an integer different from b.
